(19) United States
(12) Patent Application Publication
(10) Pub. No.: US 2021/0063802 A1
(43) Pub. Date: Mar. 4, 2021

(54) ELECTRONIC DEVICE AND METHOD FOR MANUFACTURING THE SAME

(71) Applicant: InnoLux Corporation, Miao-Li County (TW)

(72) Inventors: Hsin-Hao Huang, Miao-Li County (TW); Yu-Chih Tseng, Miao-Li County (TW); Chu-Hong Lai, Miao-Li County (TW)

(21) Appl. No.: 16/984,122

(22) Filed: Aug. 3, 2020

(30) Foreign Application Priority Data
Sep. 4, 2019 (CN) 201910832937.8

(51) Int. Cl. G02F 1/1345; G02F 1/1333; G02F 1/1335

(52) U.S. Cl. CPC G02F 1/13452; G02F 1/133528; G02F 1/133305

(57) ABSTRACT

An electronic device includes a first flexible substrate, a bonding pad and a first supporting film. The bonding pad is disposed on the first flexible substrate, and a first supporting film is attached to the first flexible substrate. The first supporting film has a first opening corresponding to the bonding pad.

### BACKGROUND OF THE DISCLOSURE

### 1. Field of the Disclosure

The present disclosure relates to an electronic device and a method for manufacturing the electronic device, in particular to an electronic device having a flexible substrate with a supporting film attached thereto, and a related manufacturing method.

### 2. Description of the Prior Art

In the manufacturing process of flexible electronic devices, it is necessary to use a machine to separate the glass carrier plate and the flexible substrate, and the worse yield rate due to insufficient flatness may occur.

Therefore, it is still necessary to research and develop the technology regarding the flexible electronic device to improve the drawbacks of the conventional technology.

### SUMMARY OF THE DISCLOSURE

In view of these, it is necessary to propose an electronic device and a manufacturing method to solve the current technical problems which the flexible electronic devices suffer.

According to one embodiment of the present disclosure, an electronic device is provided. The electronic device includes a first flexible substrate, a bonding pad, and a first supporting film. The bonding pad is disposed on the first flexible substrate, and the first supporting film is attached to the first flexible substrate. The first supporting film has a first opening which is corresponding to the bonding pad.

The embodiment of the present disclosure also provides a method of manufacturing an electronic device. First, a panel is provided. The panel includes a first flexible substrate, a bonding pad, and a first supporting film. The bonding pad is disposed on the first flexible substrate, and the first supporting film is attached to the first flexible substrate. The first supporting film has a first opening which is provided to correspond to the bonding pad of the first flexible substrate. Then, an electronic component or a circuit board is bonded onto the bonding pad.

According to the manufacturing method of the electronic device of the embodiment of the present disclosure, a robust supporting film may be used to support the flexible substrate. In addition, a flexible display with a supporting film may be obtained, in which the supporting film may have a pattern.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 5 are schematic diagrams of a method for manufacturing an electronic device according to one embodiment of the present disclosure;

FIG. 6 is a partial schematic diagram showing a supporting film according to an embodiment;

FIG. 7 to FIG. 8 are schematic diagrams of the manufacturing method of the electronic device according to an embodiment of the present disclosure;

FIG. 9 is a partial schematic diagram of an electronic device according to an embodiment of the present disclosure;

FIG. 10 is a top view corresponding to a bulk plate structure of the present disclosure;

FIG. 10A is a schematic diagram of a method for manufacturing an electronic device according to an embodiment of the present disclosure;

FIG. 10B is a schematic diagram of a method for manufacturing an electronic device according to an embodiment of the present disclosure;

FIG. 10C is a partial schematic diagram of an electronic device according to an embodiment of the present disclosure;

FIG. 11 is a schematic diagram of a manufacturing method of an electronic device according to an embodiment of the present disclosure;

FIG. 12A is a schematic diagram of a method for manufacturing an electronic device according to an embodiment of the present disclosure;

FIG. 12B is a schematic diagram of a manufacturing method of an electronic device according to an embodiment of the present disclosure.

### DETAILED DESCRIPTION

To provide a better understanding of the present disclosure to those skilled in the art, embodiments will be detailed as follows. The embodiments of the present disclosure are illustrated in the accompanying drawings with numbered elements to elaborate on the contents and effects to be achieved. It is needed to note that the drawings are simplified schematic diagrams, and therefore, the drawings show only the components and combinations associated with the present disclosure, and to provide a clearer description of the basic architecture or method of implementation of the present disclosure. The components would be complex in reality. In addition, for explanation, the components shown in the drawings of the present disclosure are not drawn to the actual number, shape, and dimensions, and the detail can be adjusted according to the design requirements.

Certain terms are used throughout the description and following claims to refer to particular components. As one skilled in the art will understand, electronic equipment manufacturers may refer to a component by different names. This document does not intend to distinguish between components that differ in name but not in function. In the following description and in the claims, the terms “include”, “comprise” and “have” are used in an open-ended fashion, and thus should be interpreted to mean “include, but not limited to . . . ”.

It will be understood that when an element or layer is referred to as being “on another component or on another layer” or “connected to another component or to another layer”, it can be directly on or directly connected to the other element or layer, or intervening elements or layers may be presented. In contrast, when an element is referred to as being “directly on” or “directly connected to” another element or layer, there are no intervening elements or layers presented.

The electronic device according to the embodiments of the present disclosure may include a display device, an antenna device, a sensing device, a light-emitting device, a tiled device, other suitable devices, or a combination of the above devices, but not limited thereto. The electronic device may be a panel itself or include a panel, and the electronic device may be a bendable or flexible device. The “flexible device” mentioned in the embodiments of the present disclosure refers to a device which may be bent, folded, rolled, flexed or other similar actions along at least one bending axis, and the directions of the bending axis may be the same or varied, but it is not limited to this. According to some embodiments, the device may be separately bent along more than two bending axes, and the directions of the bending axes may be the same or different, but it is not limited thereto.

It should be noted that the technical features in different embodiments described in the following can be replaced, recombined, or mixed with one another to constitute another embodiment without departing from the spirit of the present disclosure.

FIG. 1 to FIG. 5 are schematic diagrams of the manufacturing method of the electronic device according to embodiments of the present disclosure, and the structures in each step are illustrated in a cross-sectional presentation. The manufacturing method of the electronic device (for example, the manufacturing method of the bulk plate structure 100) of the embodiments of the present disclosure includes the following steps. Please refer to FIG. 1. Firstly, a carrier 110 is provided for carrying the components formed in the subsequent steps. The carrier 110 further includes a release layer 111 and a flexible substrate 120 which are formed in advance. The release layer 111 is disposed on the carrier 110 and indirect contact with the carrier 110, and the release layer 111 is disposed between the flexible substrate 120 and the carrier 110.

The carrier 110 may be, for example, a hard carrier, such as a glass substrate, but the present disclosure is not limited thereto. The release layer 111 may be a material which may denature or change its surface adhesion under certain conditions, and to facilitate the peeling of the carrier 110 from the electronic device. The release layer 111 may be, for example, a thin film of hydrogenated amorphous silicon (a-Si:H), but the present disclosure is not limited thereto. When the release layer 111 is a hydrogenated amorphous silicon thin film, under appropriate conditions, such as laser irradiation, hydrogen bubbles may be generated to help the carrier 110 to peel off from the flexible substrate 120. The flexible substrate 120 may be, for example, polyimide (PI), polyethylene terephthalate (PET), other suitable flexible materials, or a combination of these materials, but the present disclosure is not limited thereto. In the present disclosure, the shape of the carrier 110 may be rectangular, square, circular, polygonal or free-shape, but the present disclosure is not limited thereto.

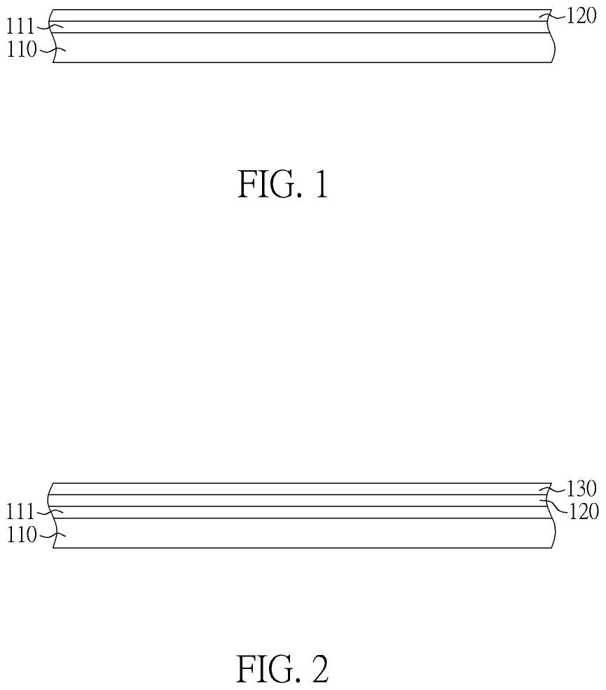

Referring to FIG. 2, a buffer layer 130 is formed on the flexible substrate 120 to facilitate the formation of subsequent elements. A deposition method may be used and the buffer layer 130 may cover the flexible substrate 120, but the present disclosure is not limited thereto. In the embodiment, the combination of the buffer layer 130, the flexible substrate 120, the release layer 111, and the carrier 110 may be regarded as a substrate unit.

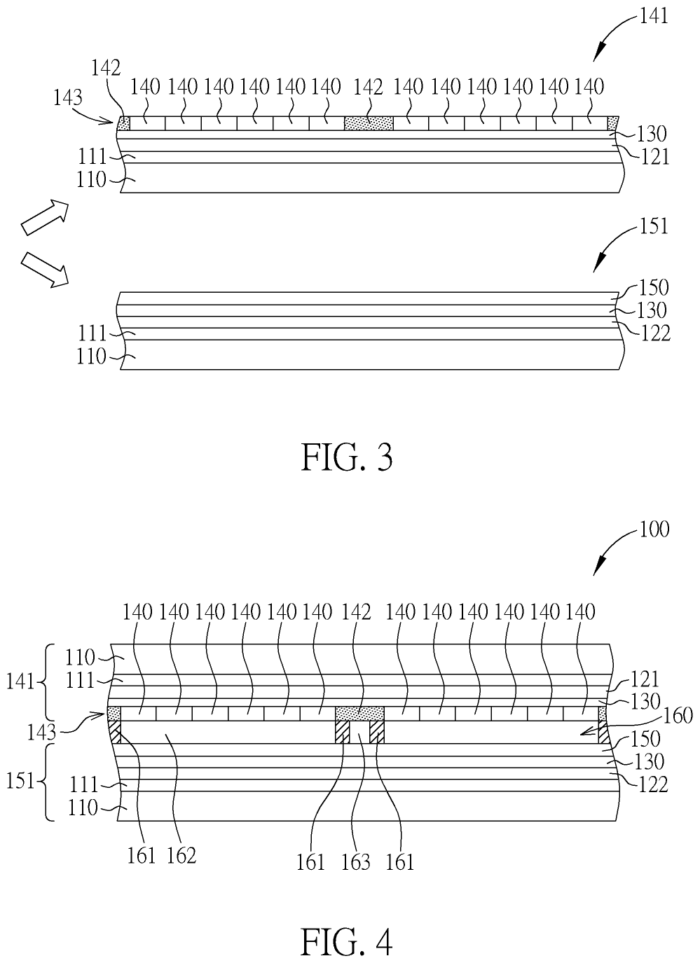

Please refer to FIG. 3, a plurality of substrate units may be manufactured by using the aforementioned method, and other components may be formed on a substrate unit. For example, a transistor array layer 150 may be formed on the first substrate unit having the first flexible substrate 122 to form the first substrate group 151. The transistor array layer 150 may include, for example but not limited to, a plurality of thin-film transistors (not shown), a plurality of data lines (not shown), and a plurality of gate lines (not shown), a plurality of pixel electrodes (not shown), a plurality of bonding pads (not shown), other wires or electronic components (not shown).

In addition, a color filter layer 143 may be formed on the second substrate unit having the second flexible substrate 121 to form the second substrate group 141. The color filter layer 143 may include a black matrix (BM) layer 142 as a light-shielding layer, and include a plurality of color filters 140. In some embodiments, the color filter layer 143 may include color filters 140 of multiple colors, such as red, blue, or green, but the present disclosure is not limited thereto. In some embodiments, a portion of black matrix layer 142 may be disposed between adjacent color filters 140, but the present disclosure is not limited thereto. In other embodiments, the color filter 140 may also be a transparent material including scattering particles or light conversion particles (such as quantum dots), but the present disclosure is not limited thereto.

It should be noted that although in this embodiment, the color filters and the transistor array are respectively disposed on flexible substrate 121 and flexible substrate 122, but the present disclosure is not limited thereto. In some embodiments, the color filters and the transistor array may also be disposed on the same flexible substrate.

Please refer to FIG. 4. Then, the second substrate group 141 and the first substrate group 151 obtained in the step of FIG. 3 are combined together to form a bulk plate structure 100. It should be noted that, in the present disclosure, the bulk plate structure 100 is referred to a bulk structure formed after the first substrate group 151 and the second substrate group 141 are combined together until it is cut into multiple panels 101, and the main parts of the entire bulk plate structure 100 are the first flexible substrate 122 and the second flexible substrate 121, and other parts may be optionally adjusted as needed. In other words, after the first substrate group 151 and the second substrate group 141 are combined together and before it is cut into multiple panels 101, the bulk structure may still be regarded as a bulk plate structure 100 even some components may be added or removed.

In the combining step, for example, the position and/or the orientation of the carriers 110 in the second substrate group 141 and in the first substrate group 151 are respectively adjusted, and a plurality of pixel electrodes in the transistor array layer 150 align with a plurality of color filters 140 in the color filter layer 143 to face each other. In addition, a sealant 161 for fixing and a medium material 162 may be disposed between the second substrate group 141 and the first substrate group 151, and the medium material 162 may be sealed in the space defined by the sealant 161, to form a medium layer 160. It should be noted that between the second substrate group 141 and the first substrate group 151 there may be still a gap 163 disposed between two adjacent sealants 161. The gap 163 is used to define the cutting line for the subsequent process steps and without filling the medium material. The position of the bonding pad (not shown) for the installation of an integrated circuit (IC) and/or a circuit board may also correspond to the gap 163. In other words, when viewing from the above in a direction perpendicular to the first flexible substrate 122, the bonding pad may be located in the area formed by the gap 163 (or the bonding pad may overlap the gap 163). In addition, it should be noted that although the medium material in the embodiments of the present disclosure may be liquid crystal exemplarily, but the present disclosure is not limited to this. In some embodiments, the medium material may be an organic light emitting diode (OLED), a light emitting diode (LED), such as a micro light-emitting diode (micro LED) or mini light-emitting diode (mini LED), quantum dot light-emitting diode (QLED/QDLED), plasma, quantum dots, fluorescent materials, phosphorescent materials, other suitable materials, or a combination of the above materials, but the present disclosure is not limited thereto.

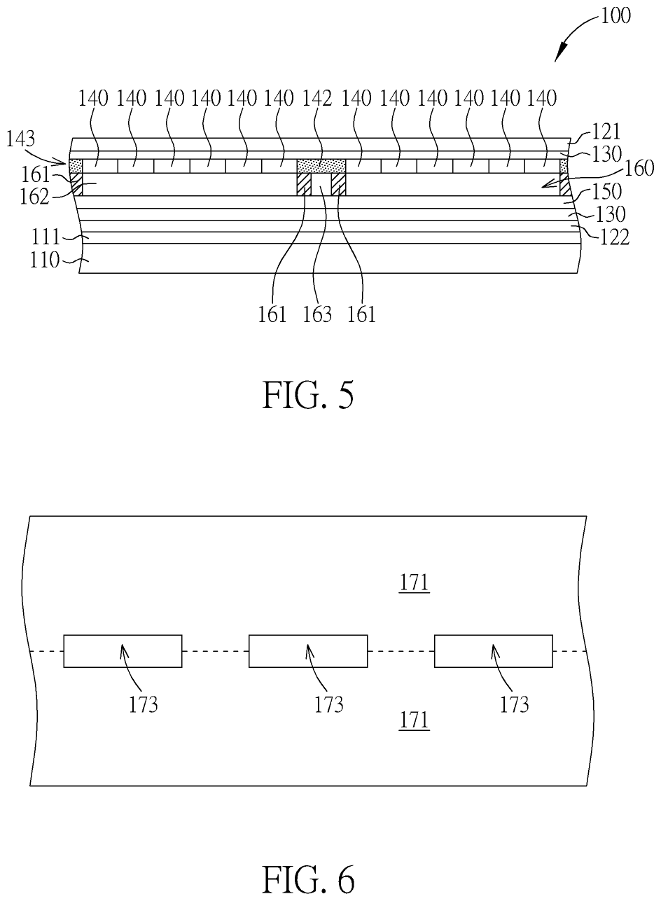

Please refer to FIG. 5, after the first substrate group 151 and the second substrate group 141 are combined together to form a bulk plate structure 100, then the step of removing the carrier 110 from the second substrate group 141 is performed. In this step, the carrier 110 of the second substrate group 141 is disposed upward or outward. Since the lower carrier 110 in the first substrate group 151 is a flat layer without an uneven surface, the yield of the removal step of the carrier 110 of the second substrate group 141 will be less affected.

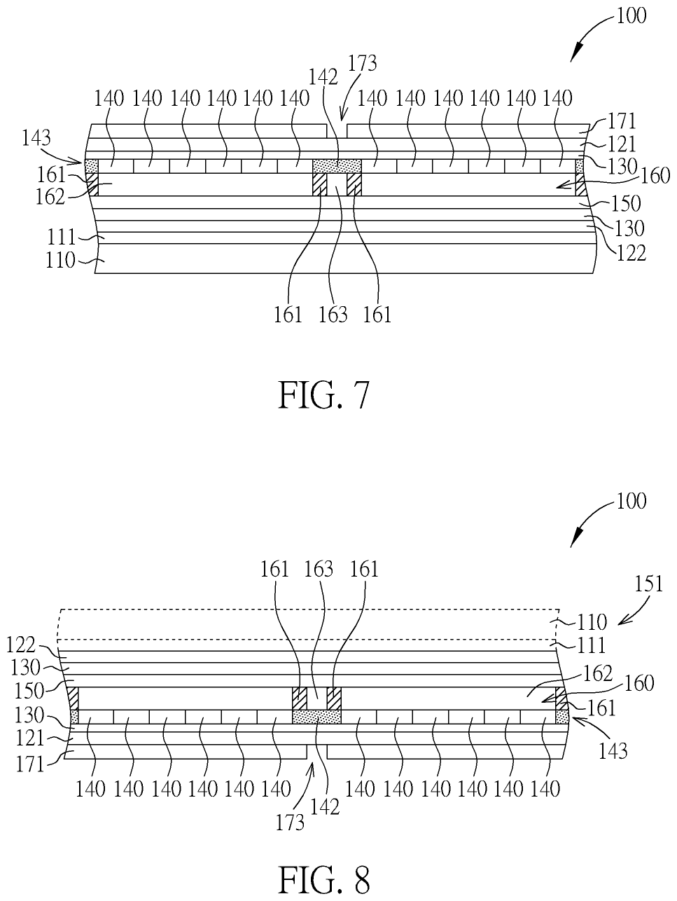

Please refer to FIG. 7. After the carrier 110 of the second substrate group 141 is removed, the second supporting film 171 may be attached to the second flexible substrate 121 by any method, to serve as one of the main supporting structures in the electronic device of the embodiments of the present disclosure.

Please refer to FIG. 6, the second supporting film 171 may be a large piece of firm material corresponding to the size of the second flexible substrate 121. The material of the second supporting film 171 may be triacetyl cellulose (TAC), but the present disclosure is not limited thereto. The second supporting film 171 may have a special shape. For example, the second supporting film 171 may have a second opening 173. In some embodiments of the present disclosure, the position of the second opening 173 may correspond to the bonding pad. In other words, when viewing from the direction perpendicular to the first flexible substrate 122, at least a part of the projection of the bonding pad on the first flexible substrate 122 is located in the projection area of the second opening 173. Similarly, since the position of the bonding pad may correspond to the gap 163, the second opening 173 may correspond to the gap 163 between the two adjacent sealants 161, that is, when viewing from the direction perpendicular to the first flexible substrate 122, the projection area of the second opening 173 in the first flexible substrate 122 at least partially overlap the projection area of the gap 163. In some embodiments, the thickness of the second supporting film 171 may be 20 microns (μm) to 100 microns (20 microns≤thickness≤100 microns), but the present disclosure is not limited thereto.

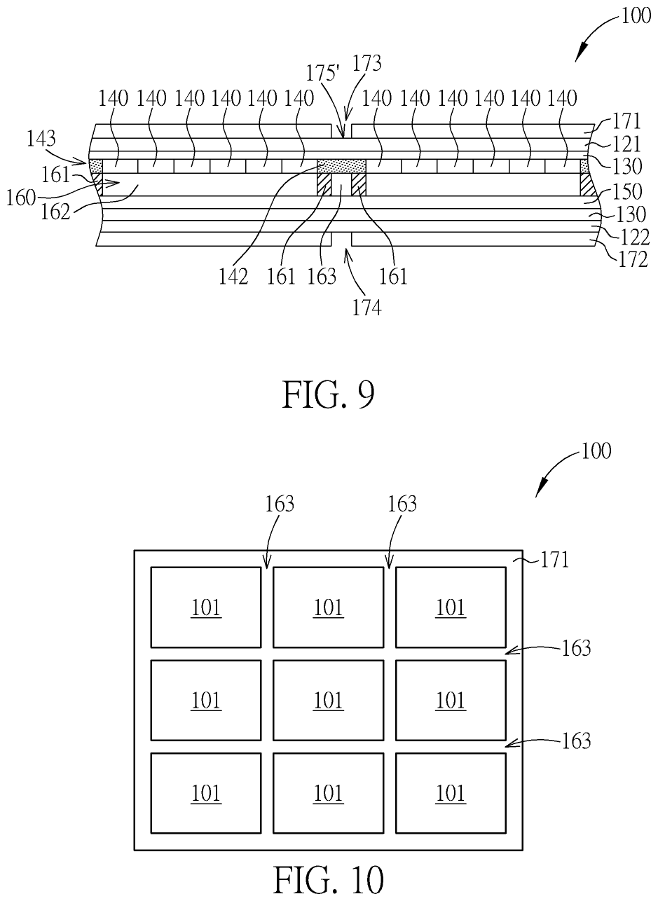

Please refer to FIG. 8 and FIG. 9. After the second supporting film 171 is provided, the step of removing the carrier 110 of the first substrate group 151 is then performed. Similarly, after the carrier 110 in the first substrate group 151 is removed, the first supporting film 172 may be provided as one of the main supporting structures in the electronic device of the embodiments of the present disclosure. The material of the first supporting film 172 may be the same as the material of the second supporting film 171, for example, it may be cellulose triacetate, but the present disclosure is not limited thereto. If the material or the thickness of the second supporting film 171 is the same as that of the first supporting film 172, it is advantageous to the matching of the stresses on the upper side and lower side of the bulk plate structure 100.

The first supporting film 172 and the second supporting film 171 may have similar shapes. For example, the first supporting film 172 may also have a first opening 174, and the position of the first opening 174 may also correspond to the bonding pad or to the gap 163.

Further, FIG. 9 illustrates the second opening 173 of the second supporting film 171 and the first opening 174 of the first supporting film 172, which correspond to each other via the same gap 163 in top and bottom position, that is, the first opening 174 of the first supporting film 172 may be provided to correspond to the second opening 173, or the projection of the first opening 174 and the second opening 173 on the first flexible substrate 122 may at least partially overlap. This is advantageous to the matching of the stresses on the upper side and lower side of the bulk plate structure 100.

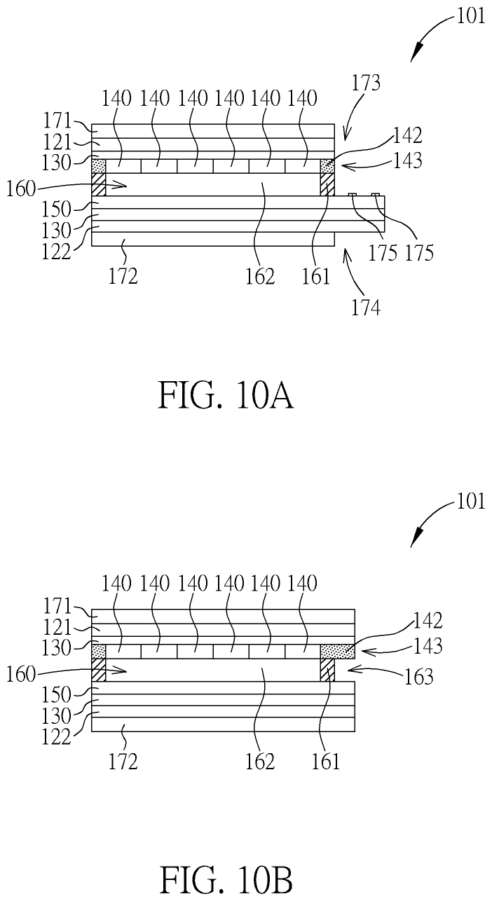

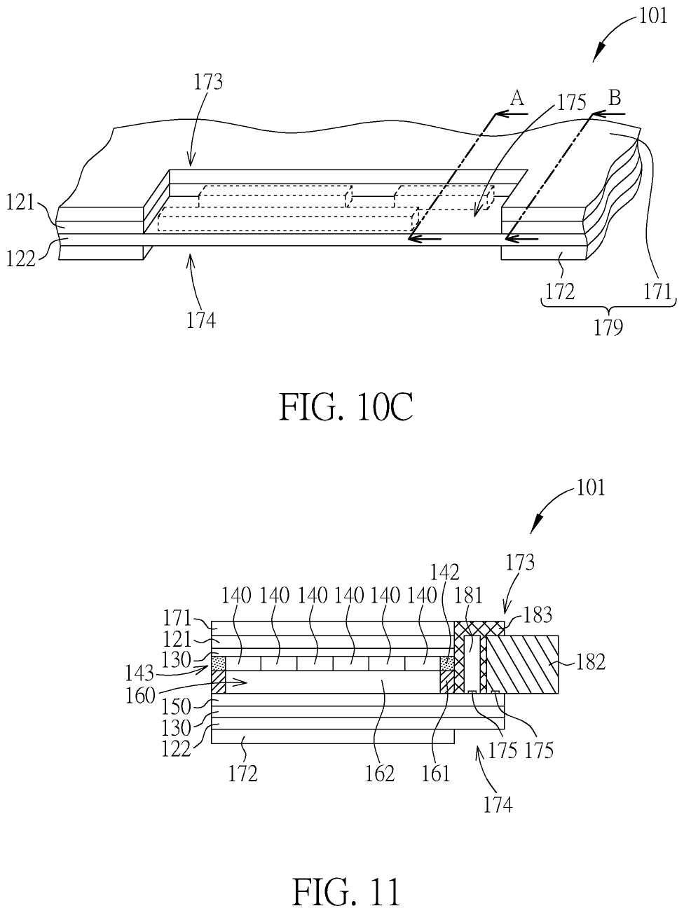

FIG. 10 is a top view corresponding to the bulk plate structure of the present disclosure. By using a conventional method such as a wheel cutter or laser, the bulk plate structure 100 is cut into a plurality of small panels 101 of a needed size. When being cut, the bulk plate structure 100 is cut into small panels 101 of a needed size according to the cutting line 163 which is defined by the previously reserved gaps 163. The panel 101 has the aforementioned reserved bonding pads (not shown).

FIG. 10C is a schematic diagram of the embodiments of the present disclosure to illustrate that the second supporting film 171 and the first supporting film 172 are used together as the main supporting structure 179 in the bulk plate structure 100 of the embodiments of the present disclosure. It should be noted that what is shown in FIG. 10C is only the area where the bonding pad 175 is possibly located, and the actual shape and number of the bonding pad 175 may vary according to the practice of the present disclosure. In addition, it should be also noted that, when the bulk plate structure 100 is formed, the second flexible substrate 121 may not have an opening corresponding to the area where the bonding pad 175 is located, and when the bulk plate structure 100 is cut, the additional steps may be needed to facilitate the formation of a substrate opening in the second flexible substrate 121 corresponding to the area where the bonding pad 175 is located. In the present embodiment, the shape and size of the substrate opening may be substantially the same as those of the second opening 173 of the second supporting film 171, and no additional numeral reference is needed here. However, in the present disclosure, the shape and the size of the opening of the second flexible substrate 121 are not limited thereto. In FIG. 10C, two lines are particularly used for the cross-sections, that is, line A and line B. The line A represents the cross section through the second opening 173 of the second supporting film 171 and through the first opening 174 of the first supporting film 172 at the same time, while the line B represents the cross section which does not pass through the second opening 173 and the first opening 174. FIG. 10A corresponds to the cross-sectional view of the previously defined line A, and FIG. 10B corresponds to the cross-sectional view of the previously defined line B, to illustrate an obtained single panel 101 after the above-mentioned cutting step. For simplicity, only the second supporting film 171, the second opening 173, the second flexible substrate 121, the first flexible substrate 122, the first supporting film 172, and the first opening 174 are schematically illustrated in FIG. 10C and other elements or element layers are omitted.

Please refer to FIGS. 10A and 10B. As shown in FIG. 10A, after the bulk plate structure 100 is cut into panels 101, a panel 101 may include a second supporting film 171, a second opening 173, a second flexible substrate 121, a buffer layer 130, and a color filter layer 143, a medium layer 160, a sealant 161, a medium material 162, a gap 163, a thin film transistor array layer 150, a buffer layer 130, a first flexible substrate 122, a first supporting film 172 and a first opening 174.

As described above, after the cutting step, as shown in FIG. 10A, the second supporting film 171, the second flexible substrate 121, the buffer layer 130 and the color filter layer 143 which correspond to the portion of the second opening 173 are removed to form a substrate opening which exposes at least one bonding pad 175 in the terminal bonding area. The bonding pad 175 may be disposed on the first flexible substrate 122, and the second supporting film 171 may be attached to the second flexible substrate 121. The second supporting film 171 may have a second opening 173 which is provided to correspond to the bonding pad 175. There may be an outer lead bonding area (OLB) for the bonding pad 175 which is reserved for the externally electrical connection of the transistor array layer 150. The shape of the second flexible substrate 121 may substantially correspond to that of the first flexible substrate 122, but it may also be partially different. For example, the second flexible substrate 121 may have a substrate opening which is provided to correspond to the bonding pad 175. It should also be noted that, according to the above description, the bonding pad 175 may be a part of the transistor array layer 150, but the present disclosure is not limited thereto. FIG. 10A shows that the bonding pad 175 located above the transistor array layer 150 is for illustration only. In fact, the position of the bonding pad 175 is not limited thereto.

Please refer to FIG. 11. FIG. 11 corresponds to the aforementioned FIG. 10A and illustrates the steps of electrically connecting the integrated circuit 181 and the circuit board 182 to the bonding pad 175 of the panel 101. As shown in FIG. 11, at least one of the integrated circuit 181 and the circuit board 182 is connected to the bonding pad 175. The circuit board 182 may be, for example, a flexible printed circuit (FPC), and the integrated circuit 181 may be, for example, a control element or a driving element of the panel 101. In the present disclosure, the second supporting film 171 and/or the first supporting film 172 may support the flexible substrate 120 to improve the yield of the bonding process when the integrated circuit 181 or the circuit board 182 is bonded onto the bonding pad 175. It should be noted that the first opening 174 which is formed in the first supporting film 172 may reduce the thermal damage, which is caused by a thermal bonding process, to the first supporting film 172 because it is possible to use a thermal bonding process such as soldering when the integrated circuit 181 or the circuit board 182 is bonded onto the bonding pad 175.

In some embodiments of the present disclosure, a waterproof glue 183 may be used to protect the integrated circuit 181 and the circuit board 182 which are disposed in the second opening 173 and on the bonding pad 175. In some embodiments of the present disclosure, the waterproof glue 183 may be in direct contact with elements, such as the second supporting film 171, the second flexible substrate 121, the buffer layer 130, the color filter layer 143, the sealant 161, the thin film transistor array layer 150 or the circuit board 182 to reduce the invasion of moisture, but the present disclosure is not limited to this.

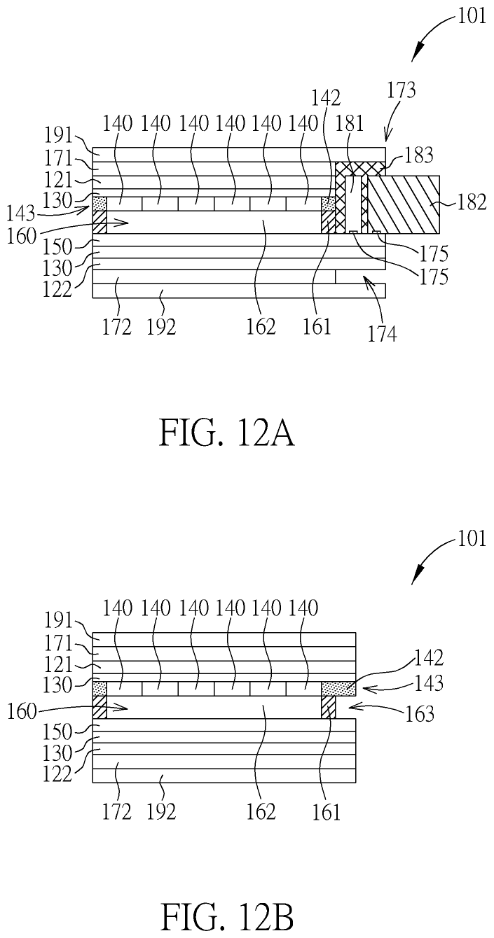

Please refer to FIG. 12A and FIG. 12B. FIG. 12A corresponds to the cross-sectional view of the previously defined line A while FIG. 12B corresponds to the cross-sectional view of the previously defined line B. As shown in FIG. 12A and in FIG. 12B, in this step of attaching of a polarizer, a polarizer of an appropriate size is attached to the outermost layer of the panel 101. For example, the second polarizer 191 of an appropriate size may be attached to the second supporting film 171, and the first polarizer 192 of an appropriate size may be attached to the first supporting film 172.

The second polarizer 191 and/or the first polarizer 192 may generally be a bulk optical film without an opening, and they are different from the second supporting film 171 or from the first supporting film 172 in structure or in shape, but the present disclosure is not limited thereto. In addition, the second polarizer 191 may cover the second supporting film 171 and the waterproof glue 183, and the second polarizer 191 may be in direct contact with the second supporting film 171 and with the waterproof glue 183 to seal the integrated circuit 181 and the circuit board 182 which are disposed in the second opening 173 and/or on the bonding pad 175, but the contact range of the second polarizer 191 is not limited to this. In addition, the first polarizer 192 may cover the first flexible substrate 122, the first opening 174, and the first supporting film 172, but the present disclosure is not limited thereto.

After the above steps, the electronic device of the present disclosure may include the second polarizer 191, the second supporting film 171, the second opening 173, the second flexible substrate 121, the buffer layer 130, the color filter layer 143, the medium layer 160, the sealant 161, the medium material 162, the gap 163, the thin film transistor array layer 150, the buffer layer 130, the first flexible substrate 122, the first supporting film 172, the first opening 174, the waterproof glue 183 and the first polarizer 192. The medium layer 160 may be disposed between the second flexible substrate 121 and the first flexible substrate 122, and the first supporting film 172 may be attached to the first flexible substrate 122. The position of the first opening 174 of the first supporting film 172 may correspond to the bonding pad 175. The integrated circuit 181 and the circuit board 182 are bonded onto the bonding pad 175.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a first flexible substrate;
a bonding pad disposed on the first flexible substrate; and
a first supporting film attached to the first flexible substrate, wherein the first supporting film has a first opening corresponding to the bonding pad.

2. The electronic device according to claim 1, comprising:
a second flexible substrate;
a liquid crystal layer disposed between the first flexible substrate and the second flexible substrate; and
a second supporting film attached to the second flexible substrate.

3. The electronic device according to claim 2, wherein the second supporting film has a second opening corresponding to the bonding pad.

4. The electronic device according to claim 2, wherein the second supporting film has a second opening corresponding to the first opening.

5. The electronic device according to claim 2, wherein the second supporting film comprises a material which is the same as a material of the first supporting film.

6. The electronic device according to claim 2, wherein a first thickness of the first supporting films is the same as a second thickness of the second supporting films.

7. The electronic device according to claim 2, further comprising a first polarizer attached to the first supporting film, and a second polarizer attached to the second supporting film.

8. The electronic device according to claim 2, wherein the second flexible substrate has a substrate opening corresponding to the bonding pad.

9. The electronic device according to claim 1, further comprising an integrated circuit or a circuit board which is bonded onto the bonding pad.

10. A method of manufacturing an electronic device, comprising:
providing a panel, the panel comprising:
a first flexible substrate;
a bonding pad disposed on the first flexible substrate; and
a first supporting film attached to the first flexible substrate and having a first opening corresponding to the bonding pad of the first flexible substrate; and
bonding an integrated circuit or a circuit board onto the bonding pad.

11. The method according to claim 10, wherein the circuit board is a flexible printed circuit (FPC).

12. The method according to claim 10, wherein the integrated circuit is a control element or a driving element of the panel.

13. The method according to claim 10, wherein the panel further comprises glue to protect the integrated circuit or the circuit board.

14. The method according to claim 10, wherein the panel comprises:
a second flexible substrate;
a liquid crystal layer disposed between the first flexible substrate and the second flexible substrate; and
a second supporting film attached to the second flexible substrate.

15. The method according to claim 14, wherein the second supporting film has a second opening corresponding to the bonding pad.

16. The method according to claim 14, wherein the second supporting film has a second opening corresponding to the first opening.

17. The method according to claim 14, wherein the second flexible substrate has a substrate opening corresponding to the bonding pad.

18. The method according to claim 10, wherein the panel further comprises:
an outer lead bonding area for the bonding pad.

19. The method according to claim 10, wherein the panel further comprises:
a first polarizer attached to the first supporting film.

20. The method according to claim 14, wherein the panel further comprises:
a second polarizer attached to the second supporting film.
